(19) United States
(12) Patent Application Publication
(10) Pub. No.: US 2024/0170608 A1
(43) Pub. Date: May 23, 2024

(54) LIGHT-EMITTING DEVICE AND LIGHT-EMITTING APPARATUS

(71) Applicant: Quanzhou Sanan Semiconductor Technology Co., Ltd., Quanzhou (CN)

(72) Inventors: Yanbin FENG, Xiamen (CN); Wenhao GAO, Xiamen (CN); Qian LIANG, Xiamen (CN); Chaoyu WU, Xiamen (CN)

(21) Appl. No.: 18/511,716

(22) Filed: Nov. 16, 2023

(30) Foreign Application Priority Data
Nov. 17, 2022 (CN) 202211468708.0

(51) Int. Cl. H01L 33/06; H01L 33/14; H01L 33/30

(52) U.S. Cl. CPC H01L 33/06; H01L 33/14; H01L 33/30

(57) ABSTRACT

A light-emitting device includes a semiconductor epitaxial structure that has a first surface and a second surface opposite to the first surface. The semiconductor epitaxial structure includes a first-type semiconductor layered unit, an active layer, and a second-type semiconductor layered unit sequentially disposed in such order in a direction from the first surface to the second surface. The active layer includes quantum well layers and quantum barrier layers stacked alternately, each of the quantum well layers includes a material that is represented by InₓGa₁₋ₓAs, and each of the quantum barrier layers includes a material that is represented by GaAs_{1-y}P_{y}, where 0.2≤x≤0.3, and 0≤y≤y0.05.

### CROSS-REFERENCE TO RELATED APPLICATION

This application claims priority to Chinese Invention Patent Application No. 202211468708.0, filed on Nov. 17, 2022, which is incorporated herein by reference in its entirety.

### FIELD

The disclosure relates to a light-emitting device and a light-emitting apparatus.

### BACKGROUND

Light-emitting diodes (LEDs) have the advantages of high light-emitting intensity, high energy efficiency, small size, long lifespan, etc., and are thus considered to be one of the light sources having the most potential. Infrared LEDs, in view of their specific wavebands as well as low power consumption and high reliability, are widely used in a diverse range of fields including safety monitoring, wearable devices, spatial communications, remote control systems, medical appliances, transducer light sources, and nighttime illumination, among others.

Currently, infrared LED products are mainly GaAs-based infrared LEDs. The typical wavelength of GaAs-based infrared LEDs is not greater than 1000 nm. A GaAs-based LED having a wavelength greater than 1000 nm may have issues such as low light-emitting efficiency and poor reliability due to massive mismatches between its active layer and a GaAs substrate. However, demand for LEDs with a wavelength of 1050 nm±50 nm is increasingly greater. There is thus an urgent need to address the issues of low light-emitting efficiency and poor reliability that may occur in the LEDs with a wavelength of 1050 nm±50 nm.

### SUMMARY

Therefore, an object of the disclosure is to provide a light-emitting device and a light-emitting apparatus that can alleviate at least one of the drawbacks of the prior art.

According to a first aspect of the disclosure, the light-emitting device includes a semiconductor epitaxial structure that has a first surface and a second surface opposite to the first surface. The semiconductor epitaxial structure includes a first-type semiconductor layered unit, an active layer, and a second-type semiconductor layered unit sequentially disposed in such order in a direction from the first surface to the second surface. The active layer includes quantum well layers and quantum barrier layers stacked alternately. Each of the quantum well layers includes a material that is represented by InₓGa₁₋ₓAs, and each of the quantum barrier layers includes a material that is represented by GaAs_{1-y}P_{y}, where 0.2≤x≤0.3, and 0≤y≤0.05.

According to a second aspect of the disclosure, the light-emitting apparatus includes the aforesaid light-emitting device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic sectional view illustrating an embodiment of a semiconductor epitaxial structure of this disclosure formed on a growth substrate.

FIG. 2 is a schematic sectional view illustrating an embodiment of a light-emitting device of this disclosure.

FIGS. 3 to 4 are schematic views illustrating a method for manufacturing the light-emitting device of the embodiment as shown in FIG. 2.

FIG. 5 is a schematic view illustrating an embodiment of a light-emitting apparatus of this disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “center,” “vertical,” “longitudinal,” “perpendicular,” “horizontal,” “top,” “bottom,” “upper,” “lower,” “front,” “rear,” “on,” “above,” “over,” “downwardly,” “upwardly,” “inner,” “outer,” and the like may be used throughout the disclosure while making reference to the features as illustrated in the drawings. The features may be oriented differently (e.g., rotated 90 degrees or at other orientations) and the spatially relative terms used herein may be interpreted accordingly.

Furthermore, the terms “first,” “second,” and other ordinal numbers used in connection with technical features are solely for descriptive purposes, and should not be understood as indicating or implying relative importance of the technical features or implying the quantity of the technical features. The quantity of any such technical feature may be one or more than one.

In the description of the present disclosure, it should also be noted that, unless otherwise specified or explicitly stated, the terms “disposed,” “installed,” “mounted,” “connected,” “coupled” and the like should be understood in a broad sense. For example, a “connection” may be a fixed connection, but it may also be a detachable connection or an integral connection; it may be a mechanical connection or an electrical connection; it may be a direct connection or an indirect connection achieved through an intermediary, or it may refer to internal communication of two components.

For the purpose of this specification, it will be clearly understood that the word “comprising” means “including but not limited to”, and that the word “comprises” has an equivalent meaning.

Unless otherwise defined, all technical and scientific terms used herein have the meaning commonly understood by a person skilled in the art to which the present disclosure belongs.

The disclosure provides a light-emitting device including an active layer having particular quantum well layers and quantum barrier layers. In the light-emitting device, compressive stress caused by lattice mismatches between the quantum well layers and a substrate (e.g., an GaAs substrate) is effectively reduced. The light-emitting device may be an infrared light-emitting device with a wavelength of approximately 1050 nm and may exhibit improved brightness and reliability.

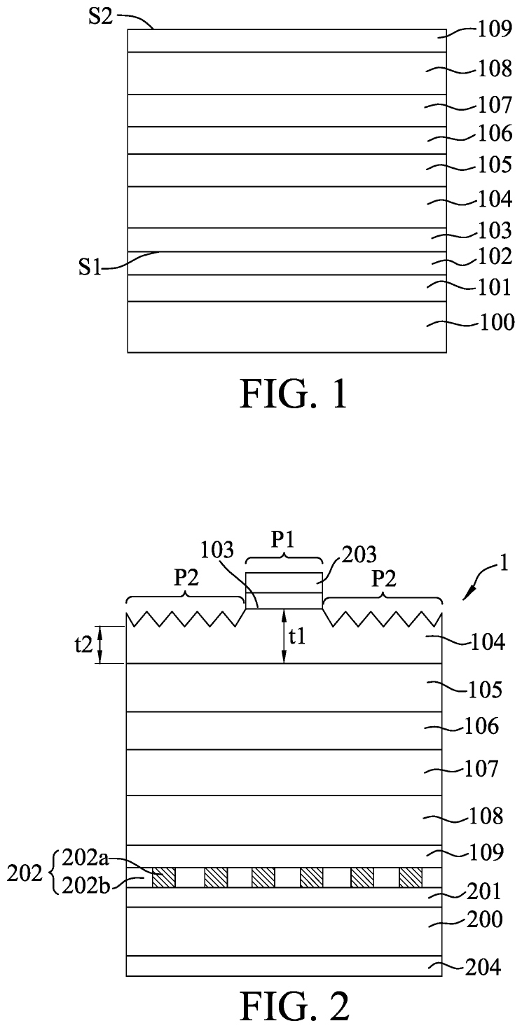

FIG. 1 is a schematic view of an embodiment of a semiconductor epitaxial structure of this disclosure formed on a growth substrate 100. The semiconductor epitaxial structure has a first surface (S1) and a second surface (S2) opposite to the first surface (S1), and includes a first current spreading layer 104, a first cladding layer 105, an active layer 106, a second cladding layer 107, a second current spreading layer 108, and a second ohmic contact layer 109 sequentially disposed on the growth substrate 100 and arranged in such order in a direction from the first surface (S1) to the second surface (S2). The first current spreading layer 104 and the first cladding layer 105 constitute a first-type semiconductor layered unit. The second cladding layer 107, the second current spreading layer 108, and the second ohmic contact layer 109 constitute a second-type semiconductor layered unit.

The growth substrate 100 may include a material such as, but is not limited to, GaAs, GaP, InP, etc. In this embodiment, the growth substrate 100 is formed from GaAs, for example. In some embodiments, the first-type semiconductor layered unit of the semiconductor epitaxial structure may further include a first ohmic contact layer 103 disposed between the growth substrate 100 and the first current spreading layer 104. In some embodiments, a buffer layer 101 and an etch stop layer 102 may also be sequentially provided between the growth substrate 100 and the first ohmic contact layer 103. The buffer layer 101 may have a better lattice quality than that of the growth substrate 100. Therefore, growing the buffer layer 101 on the growth substrate 100 is advantageous for eliminating impact of lattice defects of the growth substrate 100 upon the semiconductor epitaxial structure. The etch stop layer 102 may act as a stop layer in a chemical etching step. In some embodiments, the etch stop layer 102 is an n-type etch stop layer 102 including n-type GalnP. To facilitate a later removal of the growth substrate 100, the etch stop layer 102 is controlled to have a thickness that is not greater than 500 nm. In certain embodiments, the thickness of the etch stop layer 102 is not greater than 200 nm. In some embodiments, the first ohmic contact layer 103 includes GaAs, and has a thickness ranging from 10 nm to 100 nm, and a doping concentration ranging from 1 E+18/cm³ to 10 E+18/cm³. In certain embodiments, the doping concentration of the first ohmic contact layer 103 is 2 E+18/cm³, so as to achieve a good ohmic contact.

The semiconductor epitaxial structure may be formed on the growth substrate 100 by physical vapor deposition (PVD), chemical vapor deposition (CVD), epitaxy growth technology, or atomic layer deposition (ALD), etc.

The semiconductor epitaxial structure includes a semiconductor material capable of providing radiations of light such as ultraviolet, blue, green, yellow, red, infrared light, etc. Specifically, the semiconductor material may generate light with a wavelength ranging from 200 nm to 950 nm, such as a nitride material. More specifically, the semiconductor epitaxial structure may be a gallium nitride (GaN)-based epitaxial structure that is generally doped with elements such as aluminum (AI) and indium (In), and provides radiation primarily within a wavelength ranging from 200 nm to 550 nm. In some embodiments, the semiconductor epitaxial structure may be an aluminum gallium indium phosphide (AlGaInP)-based or aluminum gallium arsenide (AlGaAs)-based epitaxial structure which may provide radiation of light with a wavelength ranging from 550 nm to 950 nm. In this embodiment, the semiconductor epitaxial structure may be an AlGaAs-based epitaxial structure and may provide radiation of light with a wavelength ranging from 1020 nm to 1080 nm in the infrared band.

The first current spreading layer 104 is configured for current spreading. Generally, current spreading ability of the first current spreading layer 104 is depended on a thickness of the first current spreading layer 104. Accordingly, in certain embodiments, the first current spreading layer 104 may have a thickness ranging from 0 μm to 10 μm. In certain embodiments, the first current spreading layer 104 may have a thickness ranging from 2,000 nm to 10,000 nm. In this embodiment, the first current spreading layer 104 has a thickness ranging from 5000 nm to 9000 nm so as to provide uniform current spreading. Furthermore, the first current spreading layer 104 includes a material that is represented by Al_{b}Ga_{1-b}As, where 0≤b≤0.3. In some embodiment, b ranges from 0 to 0.25. Moreover, the first current spreading layer 104 may have a doping concentration ranging from 1 E+17/cm³ to 4 E+18/cm³. In certain embodiments, the first current spreading layer 104 may have a doping concentration ranging from 3 E+17/cm³ to 2 E+18/cm³.

The first cladding layer 105 and the second cladding layer 107 in the semiconductor epitaxial structure have different doping types. The doping type of a semiconductor layer is determined by a dopant that is used in doping the semiconductor layer. In this embodiment, the first cladding layer 105 is an n-type layer providing electrons, and the second cladding layer 107 is a p-type layer providing holes. The first cladding layer 105 and the second cladding layer 107 each has a bandgap that is greater than a bandgap of the active layer 106. The first cladding layer 105 may be doped with an n-type dopant, e.g., Si or Te, and the second cladding layer 107 may be doped with a p-type dopant, e.g., C or Zn. In the present embodiment, the first cladding layer 105 includes a material that is represented by AlaGa₁₋ₐAs, where “a” ranges from 0.3 to 0.45. The first cladding layer 105 has a thickness ranging from 0.3 μm to 1 μm, and a doping concentration ranging from 3 E+17/cm³ to 2 E+18/cm³, so as to provide sufficient electrons. The second cladding layer 107 may have a material, a thickness and a doping concentration the same as those of the first cladding layer 105, except for the doping type.

The active layer 106 is a region where the electrons and the holes recombine to provide light radiation. Materials for forming the active layer 106 may be determined according to a desired wavelength of light. The active layer 106 may have a single-quantum-well structure or a multiple-quantum-well structure. The active layer 106 may include at least one layer unit containing a quantum well layer and a quantum barrier layer, in which the quantum barrier layer has a greater bandgap than the quantum well layer does. By adjusting the element ratio of a material of the active layer 106, the active layer 106 may radiate light with the desired wavelength. The active layer 106 provides electroluminescent radiation and includes materials such as AlGalnP or InGaAs. In certain embodiments, the active layer 106 includes InGaAs and has either a single-quantum-well structure or a multiple-quantum-well structure. In this embodiment, the active layer 106 is a multiple-quantum-well structure and includes multiple quantum well layers and multiple quantum barrier layers stacked alternately. Each of the quantum well layers and a corresponding one of quantum barrier layers that is adjacent to the each of the quantum well layers constitute a layer unit, and the number of the layer units ranges from 3 to 15. In certain embodiments, the number of the layer units is equal to or more than 5. In certain embodiments, each of the quantum well layers includes a material that may be represented by InₓGa₁₋ₓAs, and each of the quantum barrier layers includes a material that may be represented by GaAs_{1-y}P_{y}, where 0.2<x≤0.3, and 0≤y≤0.05. Each of the quantum well layers may have a thickness ranging from 95 Å to 115 Å, and each of the quantum barrier layers may have a thickness ranging from 400 Å to 520 Å.

In manufacturing of an epitaxial structure having a light-emitting wavelength ranging from 1000 nm to 1100 nm, when each of the quantum well layers includes a material represented by InₓGa₁₋ₓAs, where x≤0.3, and has a thickness ranging from 95 Å to 115 Å, the degree of lattice mismatch between the quantum well layers including InₓGa₁₋ₓAs and a GaAs substrate may range from 1.4% to 2.1%. Such a great degree of mismatch may cause the quantum well layers to have significant compressive stress, thereby significantly affecting the light-emitting efficiency and reliability of the light-emitting device including the epitaxial structure. Such technical issues are to be addressed in this disclosure by modulating tensile strains of the quantum barrier layers so as to effectively reduce overall stress of the active layer. In this regard, prior art such as the book, Semiconductor Laser, published by Tsinghua University Press, suggests that having the thickness of a quantum barrier layer to be smaller than 10 nm is critical, under which adjusting the ratios of As and P in the material represented by GaAs_{1-y} P_{y} may achieve an overall stress balance within the structure of the active layer. However, the approach outlined in the book was found unfavorable, resulting in the presence of a substantial number of defects within the active layer and observable roughness on the surface of the semiconductor epitaxial structure. Further experimentations and analysis may demonstrate that a quantum barrier layer having a thickness smaller than the critical thickness (i.e., 10 nm) mentioned in the prior art, is infeasible for counterbalancing the significant compressive stress in the quantum well layers. Contrary to the understandings and teachings in the above book, the embodiment of this disclosure provides the quantum barrier layer having a thickness ranging from 400 Å to 520 Å, which is far greater than the mentioned critical thickness, and having the material represented by GaAs_{1-y}P_{y}, where “y” ranges from 0 to 0.05. Accordingly, the issue caused by the lattice mismatches between the quantum well layer and the substrate (e.g., a GaAs substrate) is effectively resolved. Therefore, the light-emitting efficiency and reliability of the infrared light-emitting device having a wavelength of 1050 nm±50 nm are improved.

The second current spreading layer 108 is configured for current spreading. As mentioned above, the current spreading ability of the second current spreading layer 108 is depended on a thickness of the second current spreading layer 108. Accordingly, in certain embodiments, the second current spreading layer 108 may have a thickness ranging from 0 nm to 3000 nm, so as to achieve a uniform current distribution. Furthermore, the second current spreading layer 108 includes a material that is represented by Al_{y}Ga_{1-y}As, where 0≤y≤0.25. Moreover, the second current spreading layer 108 is p-type doped, and has a doping concentrations ranging from 1 E+17/cm³ to 4 E+18/cm³.

The second ohmic contact layer 109 forms an ohmic contact with a second electrode 204 (to be described later). In some embodiments, the second ohmic contact layer 109 includes GaP, and has a doping concentration of 5 E+18/cm³ or greater. In some embodiments, the doping concentration of the second ohmic contact layer 109 is 1 E+19/cm³ or greater, so as to achieve a better ohmic contact. In some embodiments, the second ohmic contact layer 109 has a thickness ranging from 30 nm to 100 nm. In this embodiment, the second ohmic contact layer 109 has a thickness of approximately 50 nm.

FIG. 2 shows a schematic view of an embodiment of a light-emitting device 1 according to the disclosure, which includes the semiconductor epitaxial structure shown in FIG. 1. The light-emitting device 1 includes a supporting substrate 200. The semiconductor epitaxial structure is bonded onto the supporting substrate 200 through a bonding layer 201. The semiconductor epitaxial structure as aforementioned includes the second ohmic contact layer 109, the second current spreading layer 108, the second cladding layer 107, the active layer 106, the first cladding layer 105, the first current spreading layer 104, and the first ohmic contact layer 103 sequentially disposed in such order on the supporting substrate 200.

The supporting substrate 200 may be a conductive substrate, which may be made of silicon, silicon carbide, or metal. In some embodiments, the metal used for forming the substrate may be copper, tungsten, or molybdenum. In order to support the semiconductor epitaxial structure, in some embodiments, the supporting substrate 200 has a thickness of about 50 μm or more to have sufficient mechanical strength. Furthermore, to facilitate mechanical processing of the supporting substrate 200 after bonding onto the semiconductor epitaxial structure, in some embodiments, the thickness of the supporting substrate 200 is no greater than 300 μm. In this embodiment, the supporting substrate 200 is a silicon substrate.

The light-emitting device 1 further includes a first electrode 203 that is electrically connected to the first-type semiconductor layered unit. The first electrode 203 is disposed on the first ohmic contact layer 103, and forms an ohmic contact with the first ohmic contact layer 103 to enable current flows. The first ohmic contact layer 103 has a size that correspond to, and are fully covered by, the first electrode 203. The first current spreading layer 104 includes two portions in a horizontal direction that is perpendicular to the direction from the first surface (S1) to the second surface (S2): a first portion (P1) that is right below the first electrode 203, and a second portion (P2) that is not right below the first electrode 203. That is to say, when the light-emitting device 1 is viewed from above, the first portion (P1) is covered by the first electrode 203 and the first ohmic contact layer 103, and the second portion (P2) is exposed from the first electrode 203 and the first ohmic contact layer 103. The second portion (P2) has an exposed surface that is exposed from the first electrode 203 and the first ohmic contact layer 103, and serves as a light-emitting surface of the light-emitting device 1. In other words, the light-emitting surface surrounds the first electrode 203. The light-emitting surface may further be roughened into a patterned surface or a roughened surface by, e.g., etching, and may have a regular micro-nanostructure or an irregular micro-nanostructure. The roughened surface or the patterned surface may enhance light extraction, thereby improving the light-emitting efficiency of the light-emitting device 1. In certain embodiments, the light-emitting surface is roughened to have a maximum height difference (Ry) less than 1 μm, for example, ranging from 10 nm to 30 nm.

The exposed surface of the second portion (P2) of the first current spreading layer 104 is substantially lower in a horizontal level than a surface of the first portion (P1) that is in contact with the first ohmic contact layer 203, because the exposed surface of the second portion (P2) is roughened (e.g., by etching) while the surface of the first portion (P1) is protected by the first electrode 203 (and the first ohmic contact layer 103).

As shown in FIG. 2, in this embodiment, the first current spreading layer 104 includes the first portion (P1) (i.e., the portion located right below the first electrode 203) and the second portion (P2) (i.e., the portion not located right below the first electrode 203) as aforementioned. The second portion has a base and a plurality of protrusions disposed on the base. The first portion (P1) of the first current spreading layer 104 has a first thickness (t1), and the base of the second portion (P2) of the first current spreading layer 104 has a second thickness (t2). The first thickness (t1) of the first portion (P1) is greater than the second thickness (t2) of the second portion (P2). In certain embodiments, the first thickness (t1) ranges from 1.5 μm to 2.5 μm, and the second thickness (t2) ranges from 0.5 to 1.5 μm. In certain embodiments, the first thickness (t1) is greater than the second thickness (t2) by at least 0.3 μm.

The light-emitting device 1 may further include a mirror layer 202, which serves as a reflection layer, and may be disposed between the semiconductor epitaxial structure and the supporting substrate 200. The mirror layer 202 includes a p-type ohmic contact metal sublayer 202a and a dielectric material sublayer 202b. The mirror layer 202 forms an ohmic contact with the second ohmic contact layer 109, and reflects the light emitted from the active layer 106 towards the light-emitting surface of the first current spreading layer 104 or a sidewall of the semiconductor epitaxial structure so as to emit the light outwardly.

The light-emitting device 1 further includes a second electrode 204 that is electrically connected to said second-type semiconductor layered unit. In some embodiments, the second electrode 204 is disposed on one side of the supporting substrate 200 that is opposite to the semiconductor epitaxial structure. Alternatively, the second electrode 204 and the semiconductor epitaxial structure may be disposed on the same side of the supporting substrate 200.

The first electrode 203 and second electrode 204 may each include a transparent conductive material, a metallic material, or both. The transparent conductive material may be formed into a transparent conductive layer, and may be ITO or IZO. The metallic material includes at least one of GeAuNi, AuGe, AuZn, Au, Al, Pt, and Ti.

In this embodiment, by adjusting the elements and thickness of the quantum well layers and those of the quantum barrier layers included in the active layer 106, the compressive stress caused by the lattice mismatches between the quantum well layers and the growth substrate (e.g., GaAs substrate) may be reduced, and the epitaxial quality of the semiconductor epitaxial structure may be improved. Accordingly, the infrared light-emitting device 1 with a wavelength of, e.g., 1050 nm±50 nm, may have an improved light-emitting efficiency and reliability.

The light-emitting device 1 shown in FIG. 2 may be formed by a manufacturing method described below.

First, as shown in FIG. 1, the growth substrate, e.g., GaAs substrate, 100 is provided, and a semiconductor laminate is grown on the growth substrate 100 by epitaxy such as MOCVD. The semiconductor laminate includes the buffer layer 101 and the etch stop layer 102, which are later used for removing the growth substrate 100 and are sequentially disposed on the growth substrate 100. Furthermore, the epitaxial laminate further includes the semiconductor epitaxial structure which includes the first ohmic contact layer 103, the first current spreading layer 104, the first cladding layer 105, the active layer 106, the second cladding layer 107, the second current spreading layer 108, and the second ohmic contact layer 109 sequentially disposed on the etch stop layer 102 in such order.

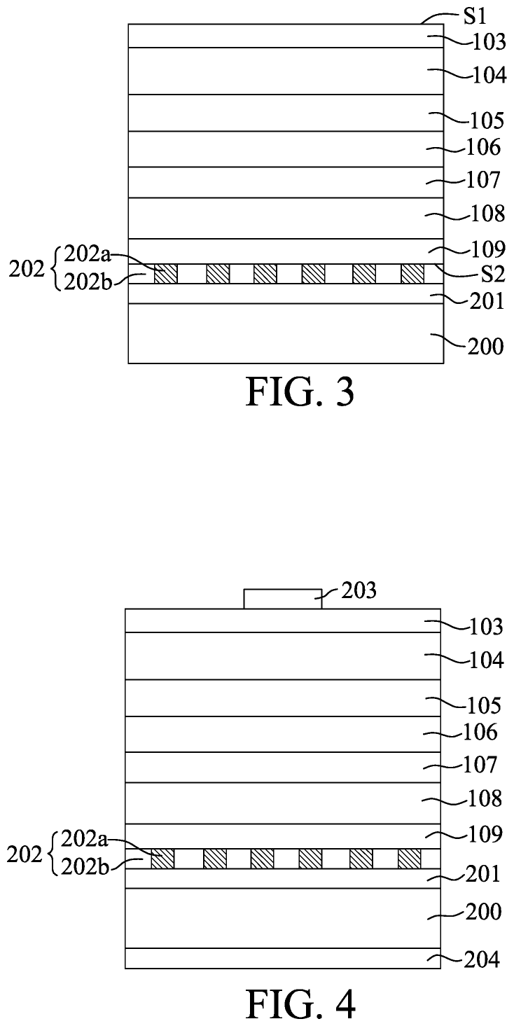

Next, the semiconductor epitaxial structure is transferred onto the supporting substrate 200 with the growth substrate 100 being removed. Specifically, as shown in FIG. 3, the mirror layer 202 is first formed on the second ohmic contact layer 109. As aforementioned, the mirror layer 202 may include the p-type ohmic contact metal sublayer 202a and the dielectric material sublayer 202b, forms the ohmic contacts with the second ohmic contact layer 109, and reflects the light emitted from the active layer. Furthermore, the supporting substrate 200 is provided and the bonding layer 201 (e.g., a metal bonding layer) is disposed on the supporting substrate 200. Subsequently, the semiconductor epitaxial structure is transferred onto the supporting substrate 200 by attaching the bonding layer 201 to the mirror layer 202, and the growth substrate 100 is removed. In the case where the growth substrate 100 is made of GaAs, a wet etching process may be performed to remove the growth substrate 100 until the first ohmic contact layer 103 is exposed.

Subsequently, as shown in FIG. 4, the first electrode 203 is disposed on the first ohmic contact layer 103, and forms a good ohmic contact with the first ohmic contact layer 103. In addition, the second electrode 204 is formed on the substrate 200 opposite to the first electrode 203 such that a current may be conducted between the first electrode 203 and the second electrode 204 through the semiconductor epitaxial structure. A portion of the first ohmic contact layer 103 is not covered by and thus is exposed from the first electrode 203.

Then, a mask (not shown) is formed to cover the first electrode 203, but not to cover the portion of the first ohmic contact layer 103 that is exposed from the first electrode 203. An etching process is performed until the portion of the first ohmic contact layer 103 that is exposed and not located right below the first electrode 203 is completely removed, and the second portion (P2) of the first current spreading layer 104 is exposed. Next, the exposed surface of the second portion (P2) of the first current spreading layer 104 is further roughened by etching, so as to obtain the light-emitting device 1 as shown in FIG. 2. The removal of the portion of the first ohmic contact layer 103 and the roughening of the exposed surface of the second portion (P2) of the first current spreading layer 104 may be carried out by a wet etching process in one step or in multiple steps. A solution used in the wet etching process may be an acidic solution, such as hydrochloric acid, sulfuric acid, hydrofluoric acid, or citric acid, or any other suitable chemical reagents.

Finally, a unitized light-emitting device 1 is obtained through processes such as etching, dicing, etc. based on actual requirements.

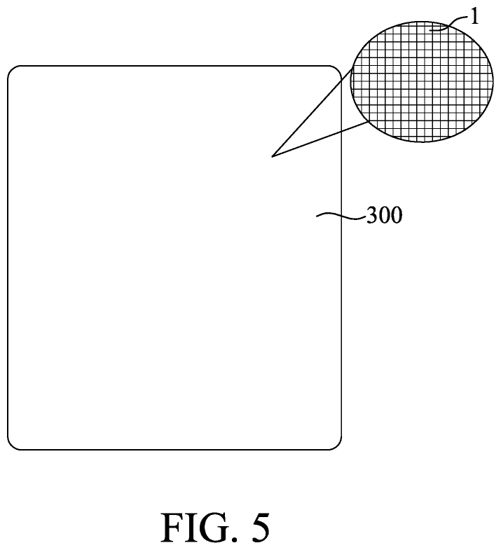

Referring to FIG. 5, an embodiment of a light-emitting apparatus 300 according to the disclosure is provided. The light-emitting apparatus 300 includes a plurality of the light-emitting devices 1 of this disclosure, each having a structure as described in any of the foregoing embodiments. The light-emitting devices 1 are arranged in an array. In FIG. 5, a portion of the array of the light-emitting devices 1 is schematically shown in an enlarged view.

In this embodiment, the light-emitting apparatus 300 may be a light source in a transducer, and may be widely used in various fields including wireless earphones, smart wearable devices, etc.

The light-emitting apparatus 300 including the light-emitting devices 1 of the embodiment(s) has the abovementioned advantages as those of the light-emitting devices 1 in this disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, the one or more features may be singled out and practiced alone without the another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial structure that has a first surface and a second surface opposite to said first surface, and that includes
a first-type semiconductor layered unit, an active layer, and a second-type semiconductor layered unit sequentially disposed in such order in a direction from said first surface to said second surface,
wherein
said active layer includes quantum well layers and quantum barrier layers stacked alternately, and
each of said quantum well layers includes a material that is represented by InₓGa₁₋ₓAs, and each of said quantum barrier layers includes a material that is represented by GaAs_{1-y}P_{y}, where 0.2≤x≤0.3, and 0≤y≤0.05.

2. The light-emitting device as claimed in claim 1, wherein each of said quantum well layers has a thickness ranging from 95 Å to 115 ΔÅ, and each of said quantum barrier layers has a thickness ranging from 400 Å to 520 Å.

3. The light-emitting device as claimed in claim 1, wherein each of said quantum well layers and a corresponding one of said quantum barrier layers that is adjacent to said each of said quantum well layers constitute a layer unit, a number of said layer unit ranging from 3 to 15.

4. The light-emitting device as claimed in claim 1, wherein said first-type semiconductor layered unit includes a first cladding layer, and said first cladding layer includes a material that is represented by AlaGa₁₋ₐAs, where 0.3≤a≤0.45.

5. The light-emitting device as claimed in claim 4, wherein said first cladding layer has a thickness ranging from 0.3 μm to 1 μm.

6. The light-emitting device as claimed in claim 4, wherein said first cladding layer has a doping concentration ranging from 3 E+17/cm³ to 2 E+18/cm³.

7. The light-emitting device as claimed in claim 1, wherein said first-type semiconductor layered unit includes a first current spreading layer, and said first current spreading layer includes a material that is represented by Al_{b}Ga_{1-b}As, where 0≤b≤0.3.

8. The light-emitting device as claimed in claim 7, wherein said first current spreading layer has a thickness ranging from 0 μm to 10 μm.

9. The light-emitting device as claimed in claim 7, wherein said first current spreading layer has a doping concentration ranging from 3 E+17/cm³ to 2 E+18/cm³.

10. The light-emitting device as claimed in claim 1, further comprising a supporting substrate and a bonding layer, said semiconductor epitaxial structure being bonded to said supporting substrate through said bonding layer.

11. The light-emitting device as claimed in claim 10, further comprising a reflection layer that is disposed between said semiconductor epitaxial structure and said supporting substrate.

12. The light-emitting device as claimed in claim 1, which radiates an invisible light having a wavelength ranging from 1000 nm and 1100 nm.

13. The light-emitting device as claimed in claim 1, wherein said second-type semiconductor layered unit includes a second cladding layer.

14. The light-emitting device as claimed in claim 1, wherein said second-type semiconductor layered unit includes a second current spreading layer, and said second current spreading layer includes a material that is represented by Al_{y}Ga_{1-y} As, where 0≤y≤0.25.

15. The light-emitting device as claimed in claim 14, wherein said second current spreading layer has a thickness ranging from 0 nm to 3000 nm.

16. The light-emitting device as claimed in claim 14, wherein said second current spreading layer has a doping concentration ranging from 1 E+17/cm³ to 4 E+18/cm³.

17. The light-emitting device as claimed in claim 1, further comprising a first electrode that is electrically connected to said first-type semiconductor layered unit, and a second electrode that is electrically connected to said second-type semiconductor layered unit.

18. The light-emitting device as claimed in claim 17, wherein said first-type semiconductor layered unit includes a first ohmic contact layer that forms an ohmic contact with said first electrode.

19. The light-emitting device as claimed in claim 17, wherein said second-type semiconductor layered unit includes a second ohmic contact layer that forms an ohmic contact with said second electrode.

20. A light-emitting apparatus comprising said light-emitting device as claimed in claim 1.
